(19) United States
(12) Patent Application Publication
(10) Pub. No.: US 2013/0155617 A1
(43) Pub. Date: Jun. 20, 2013

(54) HEAT DISSIPATION DEVICE FOR MEMORY CARD

(71) Applicants: LEI LIU, Shenzhen City (CN); GUO-YI CHEN, Shenzhen City (CN)

(72) Inventors: LEI LIU, Shenzhen City (CN); GUO-YI CHEN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/335,969

(22) Filed: Dec. 23, 2011

(30) Foreign Application Priority Data
Dec. 16, 2011 (CN) 201110423195.7

(51) Int. Cl. H05K 7/20

(52) U.S. Cl. 361/697

(57) ABSTRACT

A heat dissipation device for a memory card includes a memory slot mounted on a circuit board, a frame, and two fans. The memory slot includes a main body and two fixing portions pivotably mounted to opposite ends of the main body. The frame includes a connection bar abutted against a side surface of the main body, and two plates perpendicularly extending from opposite ends of the connection bar and positioned at opposite ends of the main body. Two hooks protrude from the connection bar respectively adjacent to the two plates to abut against opposite side surfaces of the main body. The fans are respectively fixed to the plates.

### BACKGROUND

1. Technical Field

The present disclosure relates to a device for dissipating heat generated by memory cards.

2. Description of Related Art

Some modern memory cards have large volume, and generate a great heat. If the heat is not removed rapidly, it will cause damage to the memory cards.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a heat dissipation device together with a plurality of memory cards.

FIG. 2 is an exploded, isometric view of the heat dissipation device and one of the memory cards of FIG. 1, but viewed from another perspective.

FIG. 3 is an assembled, isometric view of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

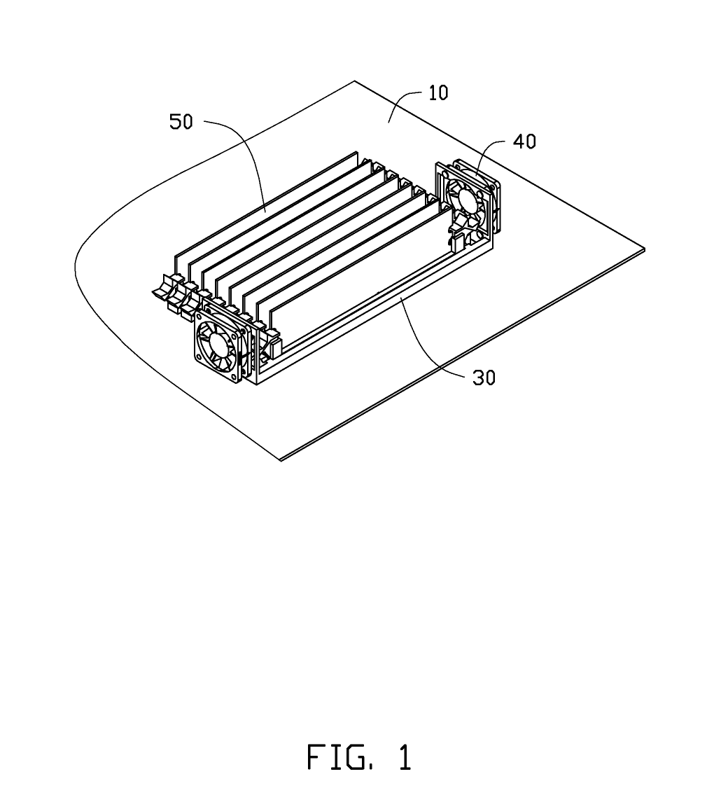

Referring to FIG. 1, an exemplary embodiment of a device for dissipating heat generated by a plurality of memory cards 50 includes a circuit board 10, a frame 30, and two fans 40.

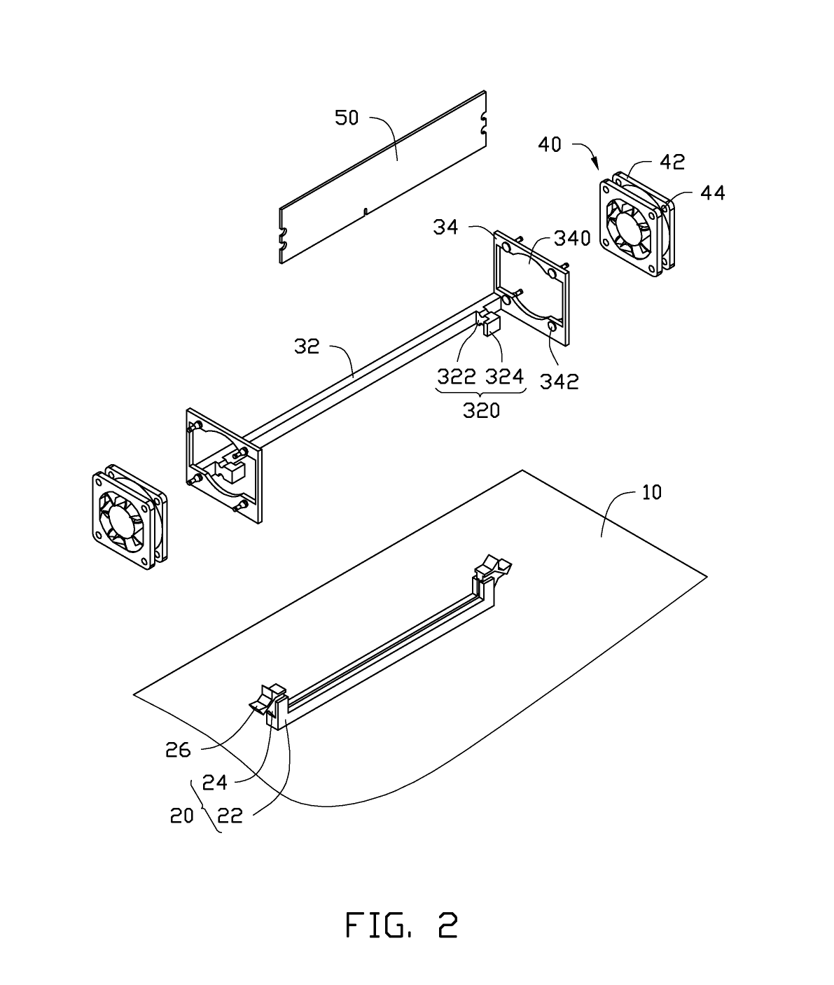

Referring to FIG. 2, a plurality of memory slots 20 for fixing the memory cards 50 is formed on the circuit board 10. Each memory slot 20 includes a main body 22 for connecting a corresponding memory card 50, and two fixing portions 24 pivotably mounted to opposite ends of the main body 22. An operation portion 26 extends from a top of each fixing portion 24 away from the other fixing portion 24.

The frame 30 includes two parallel rectangular plates 34, and a connection bar 32 perpendicularly connected between corresponding lower corners of the plates 34. A substantially L-shaped hook 320 extends from an end of an inner side surface of the connection bar 32 adjacent to each of the plates 34. The inner surface of the connection bar 32 faces the other lower corners of the plates 34. Each hook 320 includes an extension portion 322 extending from the connection bar 32 and a tab 324 extending toward the other hook 320 from a distal end of the extension portion 322 opposite to the connection bar 32. Each plate 34 defines a vent 340 in a center. Four rubber fasteners 342 are engaged in four corners of each plate 340.

Each fan 40 includes two spaced boards 42. Each board 42 defines four corner holes 44.

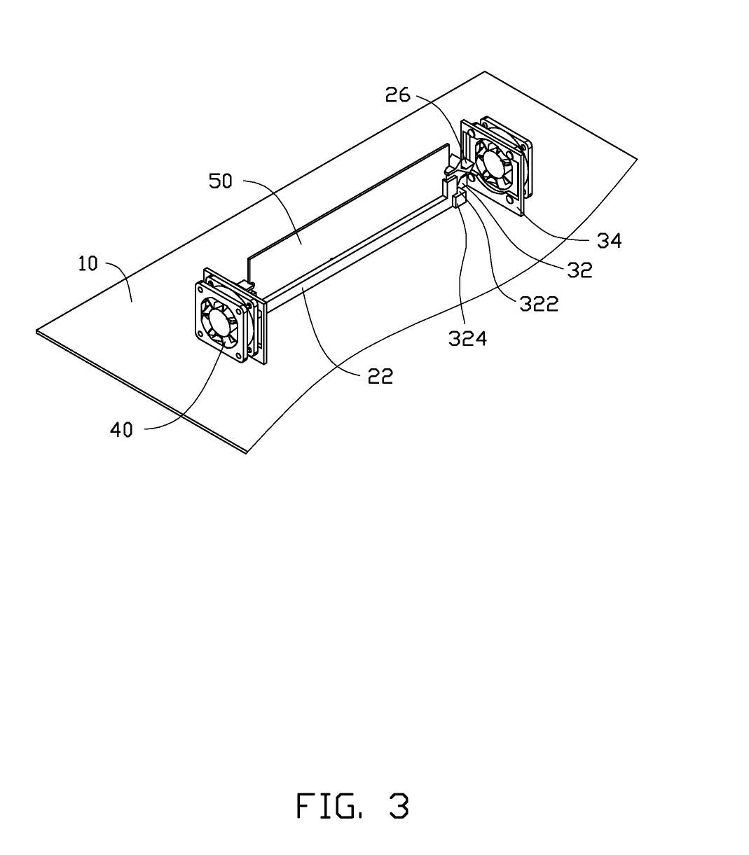

Referring to FIGS. 1 and 3, in assembly, the fixing portions 24 of an outmost memory slot 20 are pivoted toward each other, until the outmost ends of the fixing portions 24 coplanar with the corresponding end surfaces of the main body 22. The frame 30 is supported on the circuit board 10. The inner side surface of the connection bar 32 is abutted against an outer surface of the main body 22 of the outmost memory slot 20 away from the other memory slots 20. The plates 34 are located at opposite ends of the main body 22. The tabs 324 extend through spaces between the corresponding plates 34 and corresponding ends of the main body 22 to be abutted against an inner side surface of the main body 22 opposite to the connection bar 32. The extension portions 322 are abutted against the opposite ends of the main body 22. The fixing portions 24 are pivoted away from each other. A memory card 50 is inserted into the main body 22. The fixing portions 24 are pivoted back to fix opposite ends of the memory card 50. The operation portions 26 respectively block tops of the extension portions 322.

The fans 40 are respectively fixed to outer surfaces of the plates 34. The fasteners 342 of each plate 34 are engaged in the corresponding corner holes 44 of a corresponding one of the fans 40.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A heat dissipation device for dissipating heat generated by a memory card, comprising:
a frame comprising a connection bar to abut against a side surface of a memory slot, and two plates perpendicularly connected to opposite ends of the connection bar and positioned at opposite ends of the memory slot, two hooks extending from the connection bar respectively adjacent to the two plates to be engaged with opposite side surfaces of the memory slot; and
two fans respectively mounted to the plates.

2. The heat dissipation device of claim 1, wherein each plate defines a vent in a center.

3. The heat dissipation device of claim 1, wherein each plate is rectangular and forms a fastener in each of four corners to fix the corresponding fan.

4. The heat dissipation device of claim 1, wherein each hook comprises an extension portion extending from the connection bar to be abutted against one of the opposite ends of the memory slot, and a tab extending from the extension portion to be engaged with the opposite side surface of the memory slot.

5. The heat dissipation device of claim 4, wherein an operation portion extends from a top of each end of the memory slot a top of a corresponding one of the extension portions.

6. A heat dissipation device for dissipating heat generated by a memory card, comprising:
a memory slot mounted on a circuit board to connect the memory card, the memory slot comprising a main body and two fixing portions pivotably mounted to opposite ends of the main body;
a frame comprising a connection bar abutted against a side surface of the main body, and two plates perpendicularly connected to opposite ends of the connection bar and positioned at opposite ends of the main body, two hooks extending from the connection bar respectively adjacent to the two plates to be engaged with opposite side surfaces of the main body; and
two fans respectively mounted to the plates.

7. The heat dissipation device of claim 6, wherein each plate defines a vent in a center.

8. The heat dissipation device of claim 6, wherein each plate is rectangular and forms a fastener in each of four corners to fix the corresponding fan.

9. The heat dissipation device of claim 6, wherein each hook comprises an extension portion extending from the connection bar to be abutted against one of the opposite ends of the main body, and a tab extending from the extension portion to be engaged with the opposite side surface of the main body.

10. The heat dissipation device of claim 9, wherein an operation portion extends from a top of each fixing portion away from the other fixing portion to block a top of a corresponding one of the extension portions.
